(19) United States
(12) Patent Application Publication
(10) Pub. No.: US 2017/0067144 A1
(43) Pub. Date: Mar. 9, 2017

(54) VACUUM EVAPORATION SOURCE APPARATUS AND VACUUM EVAPORATION EQUIPMENT

(71) Applicant: BOE TECHNOLOGY GROUP CO., LTD., Beijing (CN)

(72) Inventors: Ronggang SHANGGUAN, Beijing (CN); Wenbin JIA, Beijing (CN); Xinxin WANG, Beijing (CN); Xinwei GAO, Beijing (CN)

(21) Appl. No.: 15/098,154

(22) Filed: Apr. 13, 2016

(30) Foreign Application Priority Data
Sep. 7, 2015 (CN) 201510563771.6

(51) Int. Cl. C23C 14/24

(52) U.S. Cl. CPC C23C 14/243

(57) ABSTRACT

A vacuum evaporation source apparatus is provided. The vacuum evaporation system includes an evaporation crucible, a first cover plate and a second cover plate. The first cover plate and the second cover plate are disposed at an outlet of the evaporation crucible. A plurality of first holes are disposed in the first cover plate penetrating its thickness direction and are evenly distributed and second via holes corresponding to the first via holes one to one are disposed in the second cover plate. The second cover plate is overlapped on the first cover plate with its position adjustable relative to the first cover plate along an extension direction of the first cover plate, and the overlapping area of each corresponding first via hole and second via hole is the same as the overlapping area of each pair of corresponding first via hole and second via hole. The second cover plate moves relative to the first cover plate and adjustment of the overlapping area of each pair of corresponding first via hole and second via hole is realized.

### CROSS REFERENCE TO RELATED APPLICATIONS

This application claims priority to China Patent Application Number 201510563771.6, which was filed on Sep. 7, 2015, the disclosure of which is incorporated by reference herein in its entirety.

### BACKGROUND

Embodiments of the present disclosure relate to the display device manufacturing field, more particularly, to a vacuum evaporation source apparatus and vacuum evaporation equipment.

During the manufacturing process of an organic light emitting diode (OLED) display device, evaporation coating is usually used to make inorganic layers and organic layers. Evaporation coating is a vacuum coating technique of physical vapor deposition, and its principle is to place the material to be evaporation coated in a crucible of a vacuum evaporation source apparatus, heat the crucible to transform the material from the solid state to gaseous atoms, atomic groups or molecules, which are then condensed onto the surface of the substrate to be film-coated, so as to form a thin film. When an OLED display panel with a large size is produced using the evaporation coating method, the evaporation coating is usually performed by keeping the vacuum evaporation source apparatus static, and making the glass substrate move horizontally above the crucible. The evaporation rates at different positions of the crucible are mainly adjusted by changing the evaporation temperatures, and such an adjustment manner often causes different evaporation rates at different positions of the crucible, which deteriorates the thickness uniformity of the thin film on the substrate, reduces the electrical and optical uniformity within the display screen, thus reducing the luminance and color uniformity of the display screen and lowering the display effect of the display screen.

### BRIEF DESCRIPTION

Embodiments of the present disclosure provide a vacuum evaporation source apparatus and vacuum evaporation equipment, which can reduce the differences of evaporation rates at different positions of the evaporation source apparatus, improve the film thickness uniformity of the evaporation material at different parts of the substrate, improve the electronic and optical uniformity within the display screen, and thus enhance the display performance of the display screen.

In order to realize the above objectives, embodiments of the present disclosure provide the following technical solutions:

A vacuum evaporation source apparatus, including an evaporation crucible, and a first cover plate and a second cover plate disposed at an outlet of the evaporation crucible; a plurality of first via holes are disposed in the first cover plate penetrating its thickness direction and evenly distributed, and second via holes corresponding to the first via holes one to one are disposed in the second cover plate; the second cover plate is overlapped on the first cover plate with its position adjustable relative to the first cover plate along an extension direction of the first cover plate, and the overlapping area of each pair of corresponding first via hole and the second via hole is the same as the overlapping area of another pair of first via hole and second via hole; when the second cover plate moves relative to the first cover plate, adjustment of the overlapping area of each pair of corresponding first via hole and second via hole is realized.

During the evaporation process of the above vacuum evaporation source apparatus, since the first via holes and the second via holes are evenly distributed, and the overlapping area of each pair of corresponding first via hole and second via hole is the same as the overlapping area of another pair of corresponding first via hole and second via hole, for the evaporation gas at different positions of the evacuation source apparatus, the distribution uniformity of the gas escaped from the overlapping parts of the first via holes and the second via holes is good. Moreover, the overlapping area of the corresponding first via holes and second via holes may be changed by adjusting the relative positions of the first cover plate and the second cover plate, so as to adjust the speed of the evaporation gas escaped from the evaporation crucible, and thus to control the evaporation rate of the vacuum evaporation source apparatus. This solution has a higher control precision as compared with the prior art method of controlling the evaporation rate by adjusting evaporation temperatures. Thus, the vacuum evaporation source apparatus can reduce the differences of evaporation rates at different positions of the evaporation source apparatus, improve the film thickness uniformity of the evaporation material at different parts of the substrate, so as to raise the electronic and optical uniformity within the display screen, and thus to enhance the overall display performance of the display screen.

According to an exemplary embodiment of the disclosure, the first via holes disposed in the first cover plate are distributed in an array, and the second via holes disposed in the second cover plate are distributed in an array.

According to an exemplary embodiment of the disclosure, in each pair of corresponding first via hole and second via hole, the size of the first via hole and of the second via hole is the same.

According to an exemplary embodiment of the disclosure, in the first cover plate, a distance between each two adjacent first via holes is 10-100 nm (nanometers).

According to an exemplary embodiment of the disclosure, the crucible is a line source crucible or surface source crucible.

According to an exemplary embodiment of the disclosure, the first via holes disposed in the first cover plate are circular holes, oval holes or polygonal holes, and the second via holes disposed in the second cover plate are circular holes, oval holes or polygonal holes.

According to an exemplary embodiment of the disclosure, the shapes of the first via holes and the second via holes are the same.

According to an exemplary embodiment of the disclosure, when the first via holes and the second via holes are circular holes, the diameters of the first via holes and the second via holes are 100 μm-5 mm.

Embodiments of the present disclosure also provide a vacuum evaporation equipment that includes the above vacuum evaporation source apparatus.

During the evaporation process of the vacuum evaporation source apparatus in the vacuum evaporation apparatus, since the first via holes and the second via holes are evenly distributed, and the overlapping area of each pair of corresponding first via hole and second via hole is the same as the overlapping area of another pair of corresponding first via hole and second via hole, for the evaporation gas at different positions of the evacuation source apparatus, the distribution uniformity of the gas escaped from the overlapping parts of the first via holes and the second via holes is good. Moreover, the overlapping area of the corresponding first via holes and second via holes may be changed by adjusting the relative positions of the first cover plate and the second cover plate, so as to adjust the speed of the evaporation gas escaped from the evaporation crucible, and thus to control the evaporation rate of the vacuum evaporation source apparatus. This solution has a higher control precision as compared with the prior art method of controlling the evaporation rate by adjusting evaporation temperatures. Thus, the vacuum evaporation source apparatus can reduce the difference of evaporation rates at different positions of the evaporation source apparatus, improve the film thickness uniformity of the evaporation material at different parts of the substrate, so as to raise the electronic and optical uniformity within the display screen, and thus to enhance the overall display performance of the display screen.

### BRIEF DESCRIPTION OF THE DRAWINGS

FIG. 1 is a structural schematic view of a vacuum evaporation source apparatus provided by a specific embodiment of the present disclosure;

FIG. 2 is a schematic view of the principle of evaporation rate adjustment of a vacuum evaporation source apparatus provided by a specific embodiment of the present disclosure.

### DETAILED DESCRIPTION

The following will describe clearly and completely the technical solutions described herein in embodiments of the present disclosure in conjunction with the accompanying drawings, The embodiments described are merely part of the embodiments of the present disclosure, and are not necessarily all of the embodiments covered by this disclosure. Based on the embodiments of the present disclosure, all other embodiments obtained by those of ordinary skill in the art without applying any creative effort shall be covered by the scope of the present disclosure.

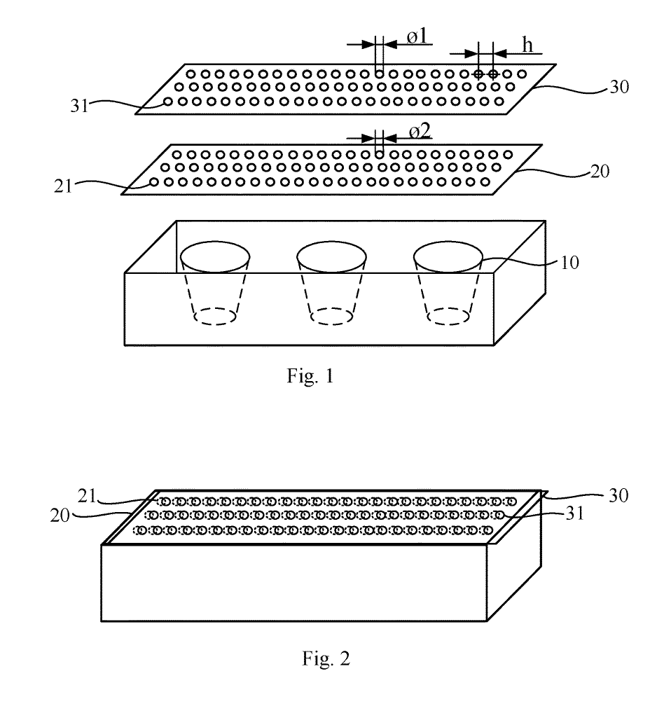

As shown in FIGS. 1 and 2, a specific embodiment of the present disclosure provides a vacuum evaporation source apparatus, that includes an evaporation crucible 10 and a first cover plate 20 and a second cover plate 30 disposed at an outlet of the evaporation crucible 10. A plurality of first via holes 21 are disposed in the first cover plate 20 penetrating its thickness direction and evenly distributed, and second via holes 31 corresponding to the first via holes 21 one to one are disposed in the second cover plate 30. The second cover plate 30 may be overlapped on the first cover plate 20 with its position adjustable relative to the first cover plate 20 along an extension direction of the first cover plate 20, and the overlapping area of each pair of corresponding first via hole 21 and second via hole 31 is the same as the overlapping area of another pair of first via hole 21 and second via hole 31. And when the second cover plate 30 moves relative to the first cover plate 20, adjustment of the overlapping area of each pair of corresponding first via hole 21 and second via hole 31 is realized.

During the evaporation coating process of the above vacuum evaporation source apparatus, since the first via holes 21 and the second via holes 31 are evenly distributed, and the overlapping area of each pair of corresponding first via hole 21 and second via hole 31 is the same as the overlapping area of another pair of corresponding first via hole 21 and second via hole 31, for the evaporation gas at different positions of the evacuation source apparatus, the distribution uniformity of the gas escaped from the overlapping part of the first via holes 21 and the second via holes 31 is good. Moreover, the overlapping area of the corresponding first via holes 21 and second via holes 31 may be changed by adjusting the relative positions of the first cover plate 20 and the second cover plate 30 so as to adjust the escaping speed of the evaporation gas from the evaporation crucible 10, and thus to control the evaporation rate of the vacuum evaporation source apparatus. Compared with the prior art method of controlling the evaporation rate by adjusting evaporation temperatures, the vacuum evaporation source apparatus of the present embodiment has a higher control precision of the evaporation rate. Thus, the vacuum evaporation source apparatus can reduce the difference of evaporation rates at different positions of the evaporation source, improving the film thickness uniformity of the evaporation material at different parts of the substrate, so as to raise the electronic and optical uniformity within the display screen, and thus to enhance the overall display performance of the display screen.

Further, in order to improve the gas distribution uniformity of the evaporation gas at different positions of the evaporation source apparatus when they escape from the overlapping parts of the first via holes 21 and the second via holes 31, in a preferred implementation shown in FIG. 1, the first via holes 21 disposed in the first cover plate 20 are arranged in an array, and the second via holes 31 disposed in the second cover plates are arranged in an array.

Further, in order to adjust the overlapping area of the first via hole and the second via hole, in a preferred implementation shown in FIG. 1, in each pair of corresponding first via hole 21 and second via hole 31, the sizes of the first via hole 21 and the second via hole 31 are the same.

Further, according to the size requirement of the evaporation source apparatus, in a preferred embodiment shown in FIG. 1, in the first cover plate, the distance h between each two adjacent first via holes is 10-100 nm; specifically, it may be 10 nm, 20 nm, 40 nm, 60 nm, 80 nm, and 100 nm.

In a preferred embodiment, in order to be adapted to the production requirement of producing display panels with large sizes, the crucible is a line source crucible or a surface source crucible.

When realizing the above functions, according to actual production requirements, the first via holes disposed in the first cover plate are circular holes, oval holes or polygonal holes, and the second via holes disposed in the second cover plate are circular holes, oval holes or polygonal holes.

Further, in order to facilitate manufacturing of the first cover plate and the second cover plate, in a preferred embodiment, the shapes of the first via holes and the second via holes are the same.

Further, according to the requirement for the evaporation rates needed during the actual production process, in a preferred embodiment shown in FIG. 1, when the first via holes and the second via holes are circular holes, the diameter (ø1) of the first via holes and the diameter (ø2) of the second via hole are 100 μm-5 mm; specifically, they may be 100 μm, 500 μm, 1 mm, 2 mm, 3 mm, 4 mm, 5 mm.

In addition, specific embodiments of the present disclosure further provide vacuum evaporation equipment, including the above vacuum evacuation source apparatus.

During the evaporation coating process of the vacuum evaporation source apparatus in the vacuum evaporation equipment, since the first via holes and the second via holes are evenly distributed, and the overlapping area of each pair of corresponding first via hole and second via hole is the same as the overlapping area of another pair of corresponding first via hole and second via hole, for the evaporation gas at different positions of the evacuation source apparatus, the distribution uniformity of the gas escaped from the overlapping parts of the first via holes and the second via holes is good. Moreover, the overlapping area of the corresponding first via holes and second via holes may be changed by adjusting the relative positions of the first cover plate and the second cover plate, so as to adjust the speed of the evaporation gas escaped from the evaporation crucible, and thus to control the evaporation rate of the vacuum evaporation source apparatus. This has a higher control precision as compared with the prior art method of controlling the evaporation rate by adjusting evaporation temperatures. Thus, the vacuum evaporation source apparatus can reduce the differences of evaporation rates at different positions of the evaporation source apparatus, improve the film thickness uniformity of the evaporation material at different parts of the substrate, so as to raise the electronic and optical uniformity within the display screen, and enhance the overall display performance of the display screen.

Obviously, those skilled in the art may make various changes and modifications to the embodiments of the present disclosure without departing from the spirit and scope of the present disclosure. Thus, if these changes and modifications of the present disclosure are within the scope of the claims of the present disclosure and equivalent techniques, the present disclosure is also intended to include these changes and modification.

1. A vacuum evaporation source apparatus, comprising:
an evaporation crucible, and
a first cover plate and a second cover plate disposed at an outlet of the evaporation crucible;
wherein a plurality of first via holes are disposed in the first cover plate penetrating its thickness direction and evenly distributed, and a plurality of second via holes corresponding to the first via holes one to one are disposed in the second cover plate;
wherein the second cover plate is overlapped on the first cover plate with its position adjustable relative to the first cover plate along an extension direction of the first cover plate, and the overlapping area of each pair of corresponding first via hole and second via hole is the same as the overlapping area of another pair of first via hole and second via hole such that when the second cover plate moves relative to the first cover plate, adjustment of the overlapping area of each pair of corresponding first via hole and second via hole is realized.

2. The vacuum evaporation source apparatus of claim 1, wherein the first via holes disposed in the first cover plate are arranged in an array, and the second via holes disposed in the second cover plates are arranged in an array.

3. The vacuum evaporation source apparatus of claim 2, wherein for each pair of corresponding first via hole and second via hole, the sizes of the first via hole and of the second via hole are the same.

4. The vacuum evaporation source apparatus of claim 2, wherein in the first cover plate, the distance between each two adjacent first via holes ranges between 10 nanometers (nm) and 100 nanometers (nm).

5. The vacuum evaporation source apparatus of claim 1, wherein the crucible is a line source crucible or surface source crucible.

6. The vacuum evaporation source apparatus of claim 1, wherein the first via holes disposed in the first cover plate are circular holes, oval holes or polygon holes, and the second via holes disposed in the second cover plate are circular holes, oval holes or polygon holes.

7. The vacuum evaporation source apparatus of claim 6, wherein the shapes of the first via holes and the second via holes are the same.

8. The vacuum evaporation source apparatus of claim 7, wherein when the first via holes and the second via holes are circular holes, the diameter of the first via holes and the second via holes is ranges between 100 micrometers (μm) and 5 millimeters (mm).

9. The vacuum evaporation source apparatus of claim 2, wherein the first via holes disposed in the first cover plate are circular holes, oval holes or polygon holes, and
wherein the second via holes disposed in the second cover plate are circular holes, oval holes or polygon holes.

10. The vacuum evaporation source apparatus of claim 9, wherein the shapes of the first via holes and the second via holes are the same.

11. The vacuum evaporation source apparatus of claim 9, wherein when the first via holes and the second via holes are circular holes, the diameter of the first via holes and the second via holes is ranges between 100 micrometers (μm) and 5 millimeters (mm).

12. The vacuum evaporation source apparatus of claim 3, wherein the first via holes disposed in the first cover plate are circular holes, oval holes or polygon holes, and
wherein the second via holes disposed in the second cover plate are circular holes, oval holes or polygon holes.

13. The vacuum evaporation source apparatus of claim 12, wherein the shapes of the first via holes and the second via holes are the same.

14. The vacuum evaporation source apparatus of claim 12, wherein when the first via holes and the second via holes are circular holes, the diameter of the first via holes and the second via holes is ranges between 100 micrometers (μm) and 5 millimeters (mm).

15. The vacuum evaporation source apparatus of claim 4, wherein the first via holes disposed in the first cover plate are circular holes, oval holes or polygon holes, and
wherein the second via holes disposed in the second cover plate are circular holes, oval holes or polygon holes.

16. The vacuum evaporation source apparatus of claim 15, wherein shapes of the first via holes and the second via holes are the same.

17. The vacuum evaporation source apparatus of claim 15, wherein when the first via holes and the second via holes are circular holes, the diameter of the first via holes and the second via holes is ranges between 100 micrometers (μm) and 5 millimeters (mm).

18. The vacuum evaporation source apparatus of claim 5, wherein the first via holes disposed in the first cover plate are circular holes, oval holes or polygon holes, and
wherein the second via holes disposed in the second cover plate are circular holes, oval holes or polygon holes.

19. The vacuum evaporation source apparatus of claim 18, wherein the shapes of the first via holes and the second via holes are the same.

20. A vacuum evaporation apparatus comprising the vacuum evaporation source apparatus of claim 1.
